(19) United States
(12) Patent Application Publication
(10) Pub. No.: US 2018/0246228 A1
(43) Pub. Date: Aug. 30, 2018

(54) RADIATION DETECTOR AND RADIATION DETECTION APPARATUS

(71) Applicant: CANON COMPONENTS, INC., Kodama-gun (JP)

(72) Inventors: Takehiro NAKAMURA, Saitama (JP); Yoshihisa NEGISHI, Saitama (JP); Akihito TAKESHITA, Saitama (JP)

(21) Appl. No.: 15/904,731

(22) Filed: Feb. 26, 2018

(30) Foreign Application Priority Data
Feb. 27, 2017 (JP) 2017-035385
Feb. 21, 2018 (JP) 2018-028839

(51) Int. Cl. G01T 1/20; G01N 23/02; H01L 27/146; H01L 31/0232

(52) U.S. Cl. CPC G01T 1/2018; G01N 23/02; H01L 31/0203; H01L 27/14663; H01L 31/02322; G01T 1/2002

(57) ABSTRACT

A radiation detector includes: an elongated wavelength conversion member that emits fluorescent light according to incident radiation; a photoelectric conversion element that receives the fluorescent light emitted from the wavelength conversion member, and generates an electrical signal; and a light condenser that is disposed between the wavelength conversion member and the photoelectric conversion element, and focuses the fluorescent light emitted from the wavelength conversion member on the photoelectric conversion element. The optical axis of the radiation incident on the wavelength conversion member and the optical axis of the light condenser extend in directions different from each other in view of the longitudinal direction of the wavelength conversion member. One focal point of the light condenser is disposed at the wavelength conversion member. The other focal point is disposed at the photoelectric conversion element.

### CROSS-REFERENCE TO RELATED APPLICATIONS

This application is based upon and claims the benefit of priority of the prior Japanese Patent Application No. 2017-035385, filed on Feb. 27, 2017, and the Japanese Patent Application No. 2018-028839, filed on Feb. 21, 2018, the entire contents of which are incorporated herein by reference.

### BACKGROUND OF THE INVENTION

### Field of the Invention

The present invention relates to a radiation detector and a radiation detection apparatus.

### Description of the Related Art

There has been a radiation detector that includes: a fluorescent body that is excited when radiation is incident, and emits fluorescent light; and a photoelectric conversion element that generates (performs photoelectric conversion for) an electrical signal according to the fluorescent light emitted from the fluorescent body. Patent Document 1 discloses a radiation image taking apparatus that includes: a planar wavelength conversion member that emits scintillation light according to incident radiation having been emitted from a radiation source and transmitted through an object; first imaging means (photoelectric conversion part) for taking an image by condensing scintillation light emitted from a radiation incident surface of the wavelength conversion member in a direction inclined from the direction of the normal of the incident surface; and second imaging means (photoelectric conversion part) for taking an image by condensing scintillation light emitted from a surface opposite to the incident surface of the wavelength conversion member in a direction inclined from the direction of the normal of the opposite surface.

Preferably, in the radiation detector, radiation is prevented from entering a sensor in order to suppress noise caused by the radiation. Unfortunately, according to the configuration of Patent Document 1, the wavelength conversion member and the first imaging element (photoelectric conversion part) and second imaging element (photoelectric conversion part) are provided at positions apart from each other. Consequently, the resolution of an image (optical image) detected by the photoelectric conversion part is reduced.

### Patent Document 1

Japanese Laid-open Patent Publication No. 2012-154735

### SUMMARY OF THE INVENTION

In view of situations described above, the present invention has an object to be achieved that suppresses radiation scattered by a fluorescent body entering a photoelectric conversion part while preventing or suppressing reduction in resolution.

To achieve the above object, the present invention includes: an elongated wavelength conversion part that emits fluorescent light according to incident radiation; a photoelectric conversion part that receives the fluorescent light emitted from the wavelength conversion part, and generates an electrical signal; and a light condensing part that is disposed between the wavelength conversion part and the photoelectric conversion part, and focuses the fluorescent light emitted from the wavelength conversion part on the photoelectric conversion part, wherein in view of a longitudinal direction of the wavelength conversion part, an optical axis of radiation incident on the wavelength conversion part, and an optical axis of the light condensing part are in directions different from each other, and one focal point of the light condensing part is disposed on the wavelength conversion part, and another focal point of the light condensing part is disposed on the photoelectric conversion part.

### BRIEF DESCRIPTION OF THE DRAWINGS

FIG. 1 is an exploded perspective view schematically showing a configuration example of a radiation detector;

FIG. 2 is an external perspective view schematically showing the configuration example of the radiation detector;

FIG. 3 is a sectional view schematically showing the configuration example of the radiation detector;

FIG. 4 is a diagram schematically showing the positional relation between a light condenser, a wavelength conversion member, and a photoelectric conversion element;

FIG. 5A is a top view schematically showing a configuration example of a supporting part;

FIG. 5B is a bottom view schematically showing the configuration example of the supporting part; and

FIG. 6 is a diagram schematically showing a configuration example of a radiation detection apparatus.

### DETAILED DESCRIPTION OF THE PREFERRED EMBODIMENTS

Hereinafter, embodiments of the present invention are described in detail with reference to the drawings. A radiation detector according to an embodiment of the present invention is used with a predetermined side of this detector being oriented toward an object and a radiation source. The radiation detector then detects and photoelectrically converts radiation that has been emitted from the radiation source and has entered the predetermined side, and generates a radiation image signal (radiation image data). The radiation detector according to the present invention includes what is called a line sensor, and can detect one-dimensional (linear) radiation. The radiation detector can generate a two-dimensional radiation image signal of the object by relatively moving with respect to the object. For the sake of convenience of description, in each diagram, the three-dimensional directions of the radiation detector are indicated by respective arrows X, Y and Z. The X direction is the longitudinal direction of a fluorescent member of the radiation detector and is, for example, the main-scan direction (the direction of arrangement of multiple light receiving parts in the line sensor). The Y direction is one short-hand direction of the radiation detector (the direction perpendicular to the longitudinal direction and the radiation incident direction) and, for example, a sub-scan direction (a relative movement direction with respect to the object during usage). The Z direction is the other short-hand direction, and is the radiation incident direction. For the sake of convenience of description, the Y direction is called a width direction, and the Z direction is called a vertical direction. With respect to the vertical direction, the predetermined side (one side that radiation enters) toward the radiation source and the object during usage is regarded as an upper side, and the opposite side is regarded as a lower side. Furthermore, an end surface of a casing (housing) of the radiation detector in the Y direction is called a side surface.

### <Radiation Detector>

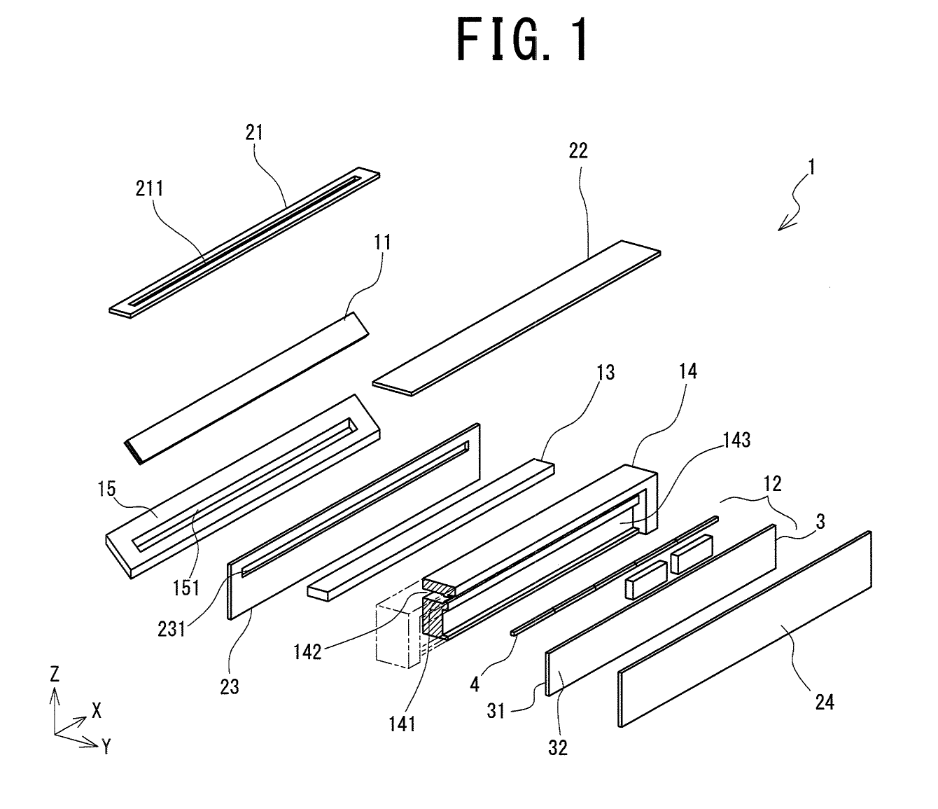

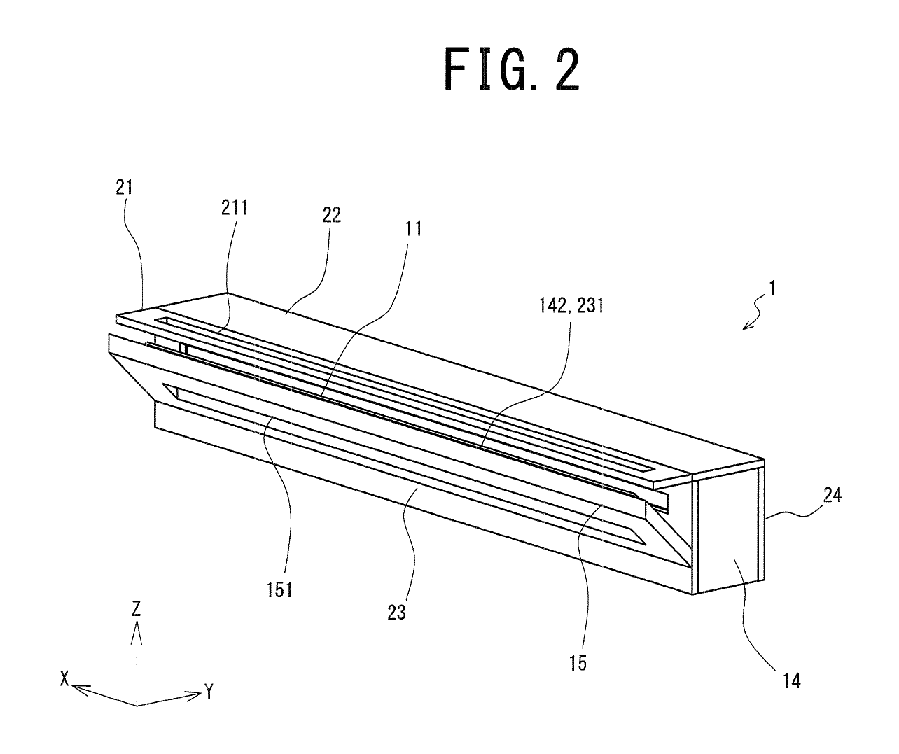

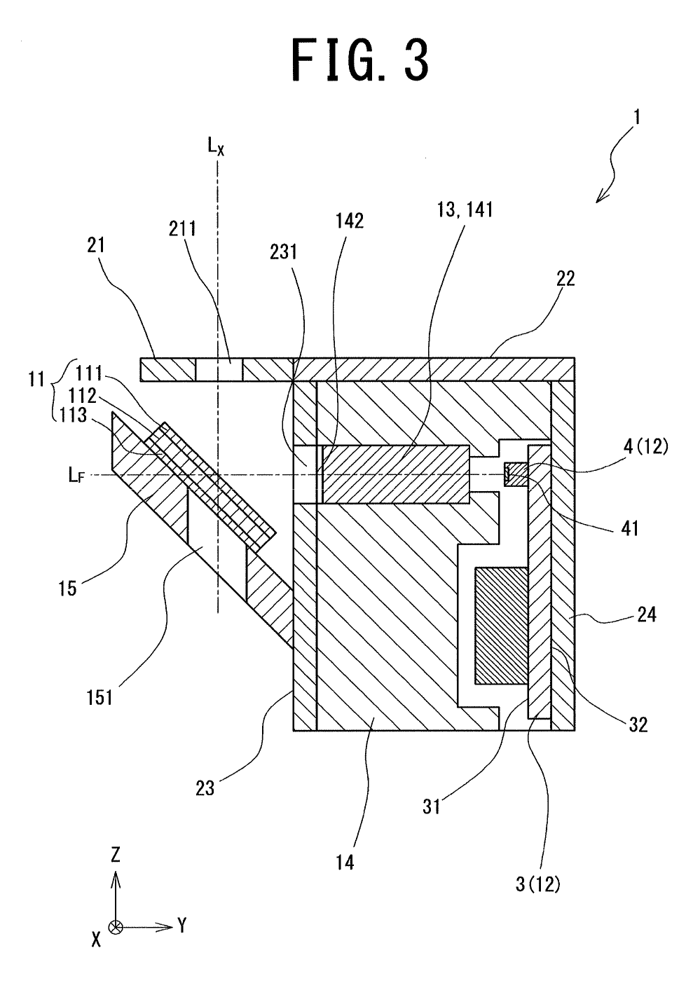

First, a configuration example of a radiation detector 1 is described with reference to FIGS. 1 to 3. FIG. 1 is an exploded perspective view schematically showing the configuration example of the radiation detector 1. FIG. 2 is an external perspective view schematically showing the configuration example of the radiation detector 1. FIG. 3 is a sectional view schematically showing the configuration example of the radiation detector 1, and shows a section taken along a plane perpendicular to the longitudinal direction of a wavelength conversion member 11. As shown in FIGS. 1 to 3, the radiation detector 1 includes: the wavelength conversion member 11 that is an example of a wavelength conversion part; a sensor substrate 12; a light condenser 13 that is an example of a light condensing part; a housing 14; and a supporting part 15. The radiation detector 1 further includes: a first blocking member 21; a second blocking member 22; a third blocking member 23; and a fourth blocking member 24.

The wavelength conversion member 11, which is the example of the wavelength conversion part, converts incident radiation into light having a wavelength which a photoelectric conversion element 4 (described later) can photoelectrically convert (visible light in the embodiment of the present invention). The wavelength conversion member 11 is a member having an elongated shape. For example, a configuration having an elongated planar shape or an elongated sheet shape is applicable. The wavelength conversion member 11 includes: a substrate layer 111; a fluorescent layer 112 provided on one surface of the substrate layer 111 in an overlapping manner; and a reflection layer 113 provided on the fluorescent layer in an overlapping manner (see FIG. 3).

For example, a plate or sheet made of a transparent material (more specifically, a material having a high transmittance of fluorescent light (visible light) emitted by the fluorescent layer 112) is applied as the substrate layer 111. For example, a plate or a sheet made of a transparent resin material, such as polyethylene terephthalate (PET), is applicable as the substrate layer 111. The fluorescent layer 112 is a layer made of a material that is excited to emit fluorescent light (visible light) when radiation enters this layer, or a layer that contains such a material. For example, a fluorescent light material, such as gadolinium oxide sulfur (GOS), cesium iodide (CSI) or amorphous selenium (A-SE), or a material that contains such a fluorescent light material is applicable as the fluorescent layer 112. The reflection layer 113 is a layer that has a high reflectance of fluorescent light emitted from the fluorescent layer 112 and has a high transmittance of radiation. For example, a material having a high reflectance of visible light and a high transmittance of radiation, such as alumina or calcium carbonate, is applicable as the reflection layer 113.

The wavelength conversion member 11 is not limited to the configuration described above. The wavelength conversion member 11 is only required to have an elongated shape, and to include the fluorescent layer 112 that is excited with incident radiation to emit fluorescent light having a wavelength that can be photoelectrically converted by the photoelectric conversion element 4. For example, the material of the fluorescent layer 112 of the wavelength conversion member 11 is not limited to the material described above. The substrate layer 111 is not limited to that of polyethylene terephthalate. Alternatively, any of various resin materials and glass can be applied as this layer. The reflection layer 113 may be made of any material that has a high reflectance of visible light and a high transmittance of radiation. In a case where the fluorescent layer 112 is made of a deliquescent material, it is preferable that the wavelength conversion member 11 include a protective layer that covers the fluorescent layer 112 so as to suppress the deliquescence of the fluorescent layer 112. In this case, a material having a highly water-shielding or water-repellent material, such as a fluorinated resin, is applicable as the protective layer.

The light condenser 13 is an example of a light condensing part. The light condenser 13 is an optical member that takes an image (focuses) the fluorescent light emitted from the wavelength conversion member 11 on a light receiving part 41 (described later) of the photoelectric conversion element 4, and has an elongated bar shape. For example, a rod lens array or a microlens array is applicable as the light condenser 13. The rod lens array includes multiple erect equal magnification imaging type imaging elements (rod lenses), which are linearly arranged in the longitudinal direction. The light condenser 13 may have any configuration that can focus linear light on the light receiving part 41 of the photoelectric conversion element 4. Consequently, the light condenser 13 is not limited to the rod lens array. The specific configuration is not specifically limited.

The sensor substrate 12 includes a wiring board 3, and a predetermined number of photoelectric conversion elements 4 mounted on the wiring board 3.

The wiring board 3 of the sensor substrate 12 has an elongated-planar configuration, for example. The wiring board 3 is provided with pads for electrical connection with the photoelectric conversion element 4, described later, and a wiring pattern that includes wiring for transmitting an electrical signal output from the photoelectric conversion element 4 to the outside. The configuration (material or the like) of the wiring board 3 is not particularly limited. Any conventionally, publicly known wiring board, such as a conventionally, publicly known printed wiring board, is applicable. The specific configuration (the number of patterns, shape, etc.) of the wiring pattern provided on the wiring board 3 is not specifically limited. The configuration is appropriately set according to the configuration of the photoelectric conversion elements 4 mounted on the wiring board 3. For the sake of convenience of description, a surface on which the photoelectric conversion elements 4 are mounted is called a first surface 31, and the opposite surface is called a second surface 32.

The multiple photoelectric conversion elements 4, as the example of the photoelectric conversion part, include multiple light receiving parts 41 that receive light emitted from the fluorescent layer 112 of the wavelength conversion member 11, and generates an electrical signal according to the fluorescent light received by the light receiving parts 41 and outputs the signal. For example, photodiode arrays are applicable as the photoelectric conversion elements 4 (photoelectric conversion part). The photodiode arrays are electronic components (elements) including multiple photodiodes as the multiple light receiving parts 41, and generates an electrical signal according to the intensity of light (light incident on the light receiving part 41) received by the light receiving part 41.

The photodiode arrays applied as the photoelectric conversion elements 4 are only required to have a predetermined number of linearly arranged light receiving parts 41. The other configuration is not specifically limited. The photoelectric conversion element 4 is not limited to the photodiodes. The photoelectric conversion element 4 may be an electronic component (element etc.) capable of converting (photoelectrically converting), into the electronic component, the fluorescent light emitted from the fluorescent layer 112 of the wavelength conversion member 11. For example, any of publicly known various types of photoelectric conversion elements, such as photodiodes or image sensor ICs, is applicable as the photoelectric conversion element 4.

Alternatively, a circuit or an element for applying a predetermined process to the electrical signal output from the photoelectric conversion element 4 may be mounted on the wiring board 3 of the sensor substrate 12. Note that the configuration of the circuit or element for processing the electrical signal output from the photoelectric conversion element 4 is not specifically limited. Alternatively, a connector for electrical connection to the outside may be mounted on the wiring board 3. In this case, the configuration of the connector is not particularly limited. Any of various publicly known connectors may be applied.

The housing 14 is a casing of the radiation detector 1. The housing 14 has an elongated rectangular parallelepiped shape or a bar shape. The longitudinal direction of the housing 14 serves as the main-scan direction of the radiation detector 1. The housing 14 is made of a material having a light blocking property. For example, any of various types of resin materials, such as polycarbonate (PC) colored in black, can be applied as the material having a light blocking property.

The housing 14 is provided with the supporting part 15 for supporting the wavelength conversion member 11. The embodiment of the present invention shows an example where the supporting part 15 is provided separately from the housing 14. Alternatively, a configuration may be adopted where the supporting part 15 is integrally provided for the housing 14. Furthermore, the housing 14 is provided with a light condenser housing part 141 that can house the light condenser 13, and a sensor substrate housing part 143 that can house the sensor substrate 12.

The supporting part 15 is a member that supports the wavelength conversion member 11, and is provided on one side surface (an end surface in the direction perpendicular to the radiation incident direction and the longitudinal direction) of the housing 14. The supporting part 15 can support the wavelength conversion member 11 so that its longitudinal direction can be oriented parallel to the longitudinal direction of the housing 14. The supporting part 15 can support the wavelength conversion member 11 so that its upper surface can be oriented inclined from the optical axis L_{X} of incident radiation and from the optical axis L_{F} of the light condenser 13 in view of the longitudinal direction of the wavelength conversion member 11. For example, a rib-shaped configuration that protrudes from the one side surface of the housing 14 and extends in the longitudinal direction is applicable as the supporting part 15. The embodiment of the present invention shows a configuration where the wavelength conversion member 11 is arranged on the upper surface (the surface on an upstream side in the radiation incident direction) of the supporting part 15. In this case, if the wavelength conversion member 11 has a sheet or planar shape, the configuration where the upper surface of the supporting part 15 is inclined from the optical axis L_{X} of the incident radiation and the optical axis L_{F} of the light condenser 13 in view of the longitudinal direction of the wavelength conversion member 11 allows the surface of the wavelength conversion member 11 to be supported in a state inclined from the optical axis L_{X} of radiation incident on the surface of the wavelength conversion member 11 and the optical axis L_{F} of the light condenser 13. FIGS. 1 to 3 show the configuration where the supporting part 15 is formed separately from the housing 14. Alternatively, the supporting part 15 may be formed integrally with the housing 14. In the case where the supporting part 15 is formed separately from the housing 14, a resin material is applicable to the supporting part 15, for example. Furthermore, the supporting part 15 is provided with a first opening 151 having a through-hole shape penetrating in the vertical direction.

The light condenser housing part 141 can house the light condenser 13 so that the longitudinal direction of the light condenser 13 and the longitudinal direction of the wavelength conversion member 11 can be the same as (in parallel to) each other and the optical axis L_{F} of the light condenser 13 and the optical axis L_{X} of the radiation incident on the wavelength conversion member 11 can be different from each other in view of these longitudinal directions. For example, the light condenser housing part 141 has a sectional shape elongated in the longitudinal direction of the housing 14 in view of the Y direction of the housing (in view of the sub-scan direction), and has a configuration having a through-hole shape penetrating from the one side surface to the sensor substrate housing part 143. The light condenser 13 can be housed in the light condenser housing part 141 so that the optical axis L_{F} can have the direction identical (parallel to) the penetrating direction of the light condenser housing part 141. An opening (i.e., an inlet of fluorescent light) of the light condenser housing part 141 is provided on the one side surface (the side surface on the side provided with the supporting part 15) of the housing 14, more upward than the supporting part 15 (on the upstream side in the radiation incident direction). For the sake of convenience of description, the opening is called a “main body opening 142”. If the light condenser housing part 141 has such a configuration, the light condenser 13 inserted (housed) in the light condenser housing part 141 is oriented so that its longitudinal direction can be identical (parallel to) the longitudinal direction of the wavelength conversion member 11 supported by the supporting part 15. In view of the longitudinal directions of the wavelength conversion member 11 and the light condenser 13, the optical axis L_{F} of the light condenser 13 has a direction different from the vertical direction of the housing 14 (i.e., the optical axis L_{X} of incident radiation).

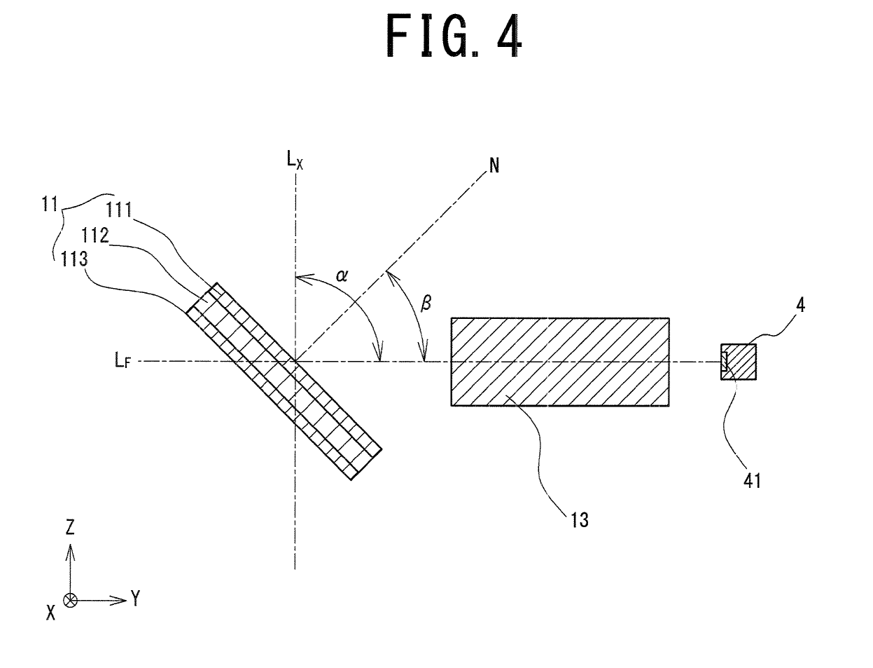

In view of the longitudinal directions of the wavelength conversion member 11 and the light condenser 13, an angle ranging from 45° to 135° is applied as the angle α (see FIG. 4) between the optical axis L_{F} of the light condenser 13 housed in the light condenser housing part 141 and the optical axis L_{X} of radiation incident on the wavelength conversion member 11. Preferably, the angle α ranges from 80° to 100°. More preferably, the angle α is 90° (right angle). FIGS. 1 to 4 show an example where the angle α is 90°.

The sensor substrate housing part 143 is provided for the housing 14 so as to be nearer to the side surface opposite to the side where the supporting part 15 is provided. The sensor substrate housing part 143 can house the sensor substrate 12 so that in view of the longitudinal direction of the housing 14, the first surface 31 of the wiring board 3 on the sensor substrate 12 can be oriented toward the supporting part 15 and the first surface 31 can be parallel to the radiation incident direction. For example, a groove or concave provided on the side surface opposite to the side surface provided with the supporting part 15 between the side surfaces of the housing 14 is applicable as the sensor substrate housing part 143. The inner surface of the sensor substrate housing part 143 and the side surface on which the supporting part 15 of the housing 14 is provided are connected to each other via the light condenser housing part 141 so as to allow fluorescent light to pass therethrough.

The first blocking member 21, the second blocking member 22, the third blocking member 23 and the fourth blocking member 24 are each made of a material having a low transmittance of radiation, or each contain a material having a low transmittance of radiation. For example, tungsten, or paper, rubber or a resin that contains tungsten is applicable to the first to fourth blocking members 21 to 24. A sheet-shaped or planar-shaped configuration is applicable to the first to fourth blocking members 21 to 24.

The first blocking member 21 is provided on the upper side of the supporting part 15 (on the upstream side in the radiation incident direction). In the vertical directional view (in view of radiation incident direction), the first blocking member 21 overlaps the first blocking member 21. More specifically, in the vertical directional view, the outer periphery of the first blocking member 21 is disposed outside of the outer periphery of the supporting part 15. The first blocking member 21 is provided with a second opening 211 serving as a radiation path. The second opening 211 has an elongated shape in the longitudinal direction of the housing 14 in the vertical directional view. A slit-shaped through-hole penetrating in the vertical direction is applied to this opening. In the vertical directional view, the first opening 151 provided for the supporting part 15 is disposed inside of the second opening 211 provided for the first blocking member 21.

The second blocking member 22 is provided on an upper side (on the upstream side in the radiation incident direction) of the sensor substrate 12 (the photoelectric conversion element 4 and the wiring board 3). In the vertical directional view, this member overlaps the sensor substrate 12 in the vertical directional view. Preferably, a configuration is adopted where in the vertical directional view, the sensor substrate 12 is housed in the outer periphery of the second blocking member 22. As shown in FIG. 3, a configuration may be adopted where the second blocking member 22 is provided so as to cover the entire upper surface of the housing 14.

The third blocking member 23 is an example of a blocking part, and is provided so as to cover the one side surface (the side surface on which the supporting part 15 is provided) of the housing 14. The third blocking member 23 is provided with a third opening 231 that allows fluorescent light to pass therethrough. The third opening 231 has a shape elongated in the longitudinal direction (main-scan direction) of the housing 14. A slit-shaped through-hole of the housing 14 penetrating in the Y direction (sub-scan direction) is applicable to this opening. In a state where the third blocking member 23 is provided so as to cover the one side surface of the housing 14, the third opening 231 integrally communicates with the opening (main body opening 142) of the light condenser housing part 141 provided for the housing 14.

The fourth blocking member 24 is provided so as to cover the other side surface (the side surface on which the supporting part 15 is not provided) of the housing 14. The fourth blocking member 24 is only required to have dimensions and a shape that can cover the other side surface of the housing 14.

Furthermore, a blocking member that covers the end surface of the housing 14 in the longitudinal direction (main-scan direction) may be provided. Moreover, a blocking member that covers the lower surface of the housing 14 may be provided.

### (Assembling Configuration of Radiation Detector)

Here, an assembling configuration of the radiation detector 1 is described.

On the first surface 31 of the wiring board 3 of the sensor substrate 12, multiple photoelectric conversion elements 4 are mounted in a linearly arranged manner. The line sensor that includes the multiple light receiving parts 41 arranged in the longitudinal direction of the wiring board 3 is thus formed. As shown in FIG. 3, the photoelectric conversion element 4 is mounted at a certain position biased to the one side of the wiring board 3 in the short-hand direction (in other words, along the one long side). Furthermore, an element, electronic and electric components, etc. for processing the electrical signal output from the photoelectric conversion element 4 may be mounted on one or both of the first surface 31 and the second surface 32 of the wiring board 3. Alternatively, a connector for electrical connection to the outside may be mounted on the wiring board 3.

The sensor substrate 12 is housed in the sensor substrate housing part 143 of the housing 14 and is fixed thereto. In the state where the sensor substrate 12 is housed in the sensor substrate housing part 143, the one long side of the wiring board 3 nearer to the photoelectric conversion element 4 is disposed on the upper side (the upstream side in the radiation incident direction). The first surface 31 of the wiring board 3 is parallel to the longitudinal direction of the wavelength conversion member 11 supported by the supporting part 15, and forms the right angle with the optical axis L_{F} of the light condenser 13 in view of the longitudinal direction of the wavelength conversion member 11.

The light condenser 13 is housed in the light condenser housing part 141, positioned, and fixed to the housing 14. The light condenser 13 housed in the light condenser housing part 141 is fixed to the housing 14 with an adhesive, such as of ultraviolet cure type, for example.

The second blocking member 22 is provided on the upper surface of the housing 14. The upper surface of the housing 14 is covered with the second blocking member 22. The second blocking member 22 does not necessarily have the configuration covering the entire housing 14. The configuration is only required to cover at least the sensor substrate 12 housed in the sensor substrate housing part 143. That is, the second blocking member 22 is disposed on the upper side (the upstream side in the radiation incident direction) of the sensor substrate 12 housed in the sensor substrate housing part 143. The configuration is only required to cover the entire sensor substrate 12 (the wiring board 3 and the photoelectric conversion element 4) in the vertical directional view.

The first blocking member 21 and the second blocking member 22 are not necessarily configured to be separated from each other. These members may be integrally configured. That is, the configuration may be adopted where a single blocking member is provided on the upper side of the housing 14, a part thereof overlaps the supporting part 15 to function as the first blocking member 21, and another part overlaps the sensor substrate 12 to function as the second blocking member 22.

The third blocking member 23 is provided on one side surface of the housing 14. The one side surface of the housing 14 is covered with the third blocking member 23. The third opening 231 provided for the third blocking member 23 communicates with the main body opening 142 (the opening of the light condenser housing part 141) provided for the housing 14. Accordingly, the optical path from the outside of the housing 14 to the light condenser 13 housed in the light condenser housing part 141 is secured.

The supporting part 15 is provided on one side surface of the housing 14. For example, in the case where the supporting part 15 is separated from the housing 14, the opposite ends of the supporting part 15 in the longitudinal direction are fixed to the respective opposite ends of the housing 14. Such a configuration can attach the supporting part 15 to the housing 14 without providing the third blocking member 23 with any opening other than the third opening 231. Note that a configuration may be adopted where the supporting part 15 is provided integrally with the housing 14. In this case, a configuration may be adopted where the third blocking member 23 is provided with an opening in order to avoid interference with the supporting part 15.

The wavelength conversion member 11 is disposed on the upper surface of the supporting part 15. For example, the wavelength conversion member 11 is caused to adhere to the upper surface of the supporting part 15 with an adhesive or the like. Accordingly, the wavelength conversion member 11 is in a state of being supported by the supporting part 15. The wavelength conversion member 11 is arranged to be oriented so that the reflection layer 113 can be disposed on the lower side and the substrate layer 111 can be disposed on the upper side. The upper surface of the supporting part 15 is inclined from the optical axis L_{X} of the incident radiation in view of the longitudinal direction of the housing 14. Accordingly, the surface of the wavelength conversion member 11 supported by the supporting part 15 comes into the state of being inclined from the optical axis L_{X} of the incident radiation. The wavelength conversion member 11 is arranged to be oriented so that its upper surface can obliquely face the one side surface of the housing 14.

The upper surface of the wavelength conversion member 11 is disposed on one focal point F₁ of the light condenser 13. The light receiving part 41 of the photoelectric conversion element 4 on the sensor substrate 12 is disposed on the other focal point F₂ of the light condenser 13. As described above, in view of the longitudinal directions of the wavelength conversion member 11 and the light condenser 13, the first surface 31 of the wiring board 3 is perpendicular to the optical axis L_{F} of the light condenser 13. Consequently, the surface of the light receiving part 41 of the photoelectric conversion element 4 mounted on the first surface 31 of the wiring board 3 is also perpendicular to the optical axis L_{F} of the light condenser 13. According to such a configuration, the fluorescent light emitted from the fluorescent layer 112 of the wavelength conversion member 11 is imaged (focused) on the light receiving part 41 of the photoelectric conversion element 4 by the light condenser 13. As described above, in view of the longitudinal directions of the wavelength conversion member 11 and the light condenser 13, the angle α between the optical axis L_{F} of the light condenser 13 and the optical axis L_{X} of the radiation incident on the wavelength conversion member 11 ranges from 45° to 135°. The photoelectric conversion element 4 receives fluorescent light traveling in a direction different from the radiation incident direction, and photoelectrically converts the light. In view of the longitudinal direction of the light condenser 13, the optical axis L_{F} of the light condenser 13 and the light receiving part 41 form the right angle. Accordingly, what is called the focal plane of the focal point F₂ of the light condenser 13 and the surface of the light receiving part 41 coincide (in parallel to) each other. Consequently, reduction in MTF can be prevented or suppressed.

The wavelength conversion member 11 may have a configuration where its lower surface is oriented to face obliquely one side surface of the housing 14 (i.e., the photoelectric conversion element 4). In this case, the inclined direction of the supporting part 15 in view of the longitudinal direction of the housing 14 is opposite to the direction indicated in FIGS. 1 to 3. The wavelength conversion member 11 is provided to be oriented so that the substrate layer 111 is disposed on the lower surface side and the reflection layer 113 is disposed on the upper surface side. In this case, the lower surface of the wavelength conversion member 11 is disposed on the one focal point F₁ of the light condenser 13. Even such a configuration can also exert the same advantageous effects as described above.

As described above, the embodiment of the present invention has the configuration where the light condenser 13 is disposed between the sensor substrate 12 and the wavelength conversion member 11. Accordingly, the fluorescent light emitted from the wavelength conversion member 11 is imaged (focused) on the light receiving part 41 of the photoelectric conversion element 4 by the light condenser 13. Furthermore, the third blocking member 23 intervenes between the sensor substrate 12 and the wavelength conversion member 11. The third blocking member 23 is provided with the third opening 231 that allows fluorescent light to pass therethrough. Accordingly, the fluorescent light emitted from the wavelength conversion member 11 is imaged (focused) on the light receiving part 41 of the photoelectric conversion element 4 through the third opening 231 provided for the third blocking member 23.

Although symbol 231 thus denotes the opening, it is only required to allow the fluorescent light to pass therethrough. For example, a configuration where transparent glass or transparent resin is arranged may be adopted. The transparent glass may contain, for example, an element having a radiation blocking property, such as lead (Pb), barium (Ba), or tungsten (W). This configuration can further suppress the radiation that is to be scattered by the wavelength conversion part and to enter the light receiving part 41 of the photoelectric conversion element 4.

The transparent member that contains the element having the radiation blocking property (e.g., transparent glass or transparent resin) has a configuration of being disposed at the opening 231 (the configuration of arrangement between the wavelength conversion member 11 and the light condenser 13), or a configuration where of being arranged between the light condenser 13 and the wavelength conversion member 11. Alternatively, a configuration of being provided for both these configuration elements may be adopted. Such a configuration can further suppress the radiation that is to be scattered by the wavelength conversion member 11 and to enter the light receiving part 41 of the photoelectric conversion element 4. The configuration where the transparent member is arranged at the opening 231 can suppress radiation incident on the light condenser 13, and suppress the damage on the light condenser 13 due to the radiation. According to the configuration where the transparent member is provided between the light condenser 13 and the wavelength conversion member 11, the radiation attenuated by the light condenser enters the transparent member. Consequently, this configuration can allow the transparent member to absorb the radiation more efficiently and can further suppress the radiation that is to enter the light receiving part 41 of the photoelectric conversion element 4 than the configuration where the transparent member is disposed at the opening 231. Alternatively, the transparent member may be arranged between the wavelength conversion member 11 and the light condenser 13 and between the light condenser 13 and the photoelectric conversion element 4. This configuration can further suppress the radiation that is to enter the light receiving part 41 of the photoelectric conversion element 4. Preferably, these configurations are selected and used in conformity with the object.

### (Operation of Radiation Detector)

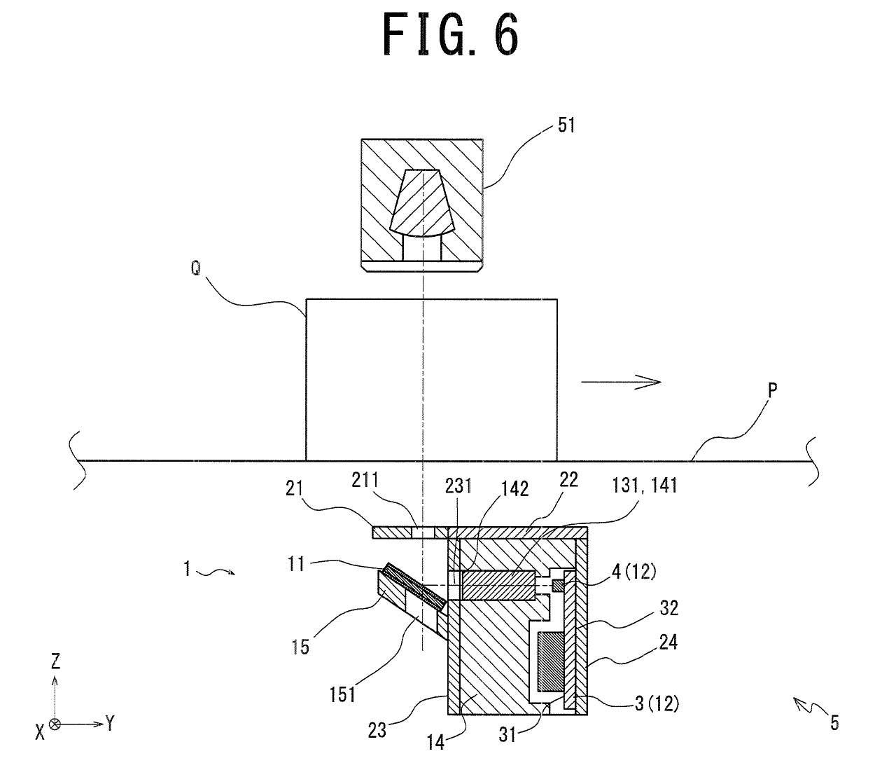

Here, the operation of the radiation detector 1 is described. The radiation detector 1 is arranged at the position apart from the radiation source 51 (see FIG. 6) and used. The radiation detector 1 is disposed so that the side allowing radiation to be incident thereon (the side where the first blocking member 21 and the second blocking member 22 are provided) can be oriented toward the side of the radiation source 51 (in other words, the upstream side of the incident radiation with respect to the traveling direction) to allow the radiation emitted from the radiation source 51 to be incident. While an object Q is caused to pass through the radiation source 51 and the radiation detector 1, the radiation source 51 emits radiation toward the object Q and the radiation detector 1 detects the radiation having transmitted through the object Q.

The first blocking member 21 is provided on the upper side of the supporting part 15. The first blocking member 21 is provided with the second opening 211. Accordingly, the radiation having emitted from the radiation source 51 and passed through the object Q further passes through the second opening 211 provided for the first blocking member 21, and enters the wavelength conversion member 11.

When the radiation enters the wavelength conversion member 11, the fluorescent layer 112 of the wavelength conversion member 11 is excited and emits fluorescent light (here, visible light). The fluorescent light emitted from the fluorescent layer 112 passes through the third opening 231 provided for the third blocking member 23 and through the light condenser 13 housed in the light condenser housing part 141 of the housing 14, and enters the light receiving part 41 of the photoelectric conversion element 4 on the sensor substrate 12. The light condenser 13 is positioned so that its one focal point F₁ can be disposed on the upper surface of the wavelength conversion member 11 and the other focal point F₂ can be disposed on the light receiving part 41 of the photoelectric conversion element 4 on the sensor substrate 12. As described above, the light condenser 13 may be positioned so that the one focal point F₁ can be disposed on the lower surface of the wavelength conversion member 11. Accordingly, the fluorescent light emitted from the fluorescent layer 112 is imaged (focused) on the light receiving part 41 of the photoelectric conversion element 4 on the sensor substrate 12 by the light condenser 13.

The photoelectric conversion element 4 on the sensor substrate 12 generates an electrical signal according to the intensity of the fluorescent light incident on the light receiving part 41, and outputs the signal. A signal that is one line of an image signal is generated from the electrical signal according to the intensity of the fluorescent light incident on the multiple light receiving parts 41 in a certain one sampling timing by the element or circuit that is provided on the sensor substrate 12 for image processing. The radiation detector 1 continuously performs such an operation in a sampling period, thereby allowing a two-dimensional radiation image signal (radiation image data) including internal information on the object Q to be generated and output.

### (Positional Relations Between Light Condenser, Wavelength Conversion Member, and Photoelectric Conversion Element)

Here, the positional relations between the light condenser 13, the wavelength conversion member 11 and the photoelectric conversion element 4 are described with reference to FIG. 4. FIG. 4 is a diagram schematically showing the positional relations between the light condenser 13, the wavelength conversion member 11 and the photoelectric conversion element 4, and is a diagram in view of the longitudinal direction of the wavelength conversion member 11 and the light condenser 13.

The radiation enters the wavelength conversion member 11 and is scattered. When the scattered radiation enters the photoelectric conversion element 4, the radiation possibly causes noise. Accordingly, to prevent or suppress occurrence of noise, it is preferred that entrance of the scattered radiation into the photoelectric conversion element 4 be prevented or suppressed. According to the embodiment of the present invention, the wavelength conversion member 11 and the photoelectric conversion element 4 are provided in a manner separated from each other. Consequently, entrance of the radiation scattered by the wavelength conversion member 11 into the photoelectric conversion element 4 is suppressed. The light condenser 13 is disposed between the wavelength conversion member 11 and the photoelectric conversion element 4. This light condenser 13 images (focuses) the fluorescent light emitted from the wavelength conversion member 11 on the photoelectric conversion element 4. Consequently, reduction or suppression of the resolution of a radiation image can be facilitated (improvement in MTF is facilitated).

Furthermore, according to the embodiment of the present invention, the light condenser 13, the wavelength conversion member 11 and the photoelectric conversion element 4 thus have the positional relations as shown in FIG. 4, thereby allowing noise prevention or suppression to be facilitated (improvement in MTF is facilitated). That is, the intensity of radiation scattered by the wavelength conversion member 11 is weakest in a direction perpendicular to the incident direction on the wavelength conversion member 11, and becomes stronger as the direction approaches a direction parallel to the incident direction. According to the embodiment of the present invention, in view of the longitudinal direction of the wavelength conversion member 11, the angle α between the optical axis L_{X} of radiation entering the wavelength conversion member 11 and the optical axis L_{F} of the light condenser 13 is assumed to range from 45° to 135°. According to such a configuration, the photoelectric conversion element 4 is provided in the direction where the radiation scattered by the wavelength conversion member 11 is weak. Consequently, entrance of the radiation scattered by the wavelength conversion member 11 into the photoelectric conversion element 4 can be suppressed. Preferably, the angle α ranges from 80° to 100°. More preferably, the angle α is 90° (right angle). If the angle α ranges from 80° to 100°, the intensity of radiation incident on the photoelectric conversion element 4 can be further reduced. If the angle α is 90°, the intensity of radiation incident on the photoelectric conversion element 4 can be the lowest. Consequently, occurrence of noise can be prevented or suppressed.

As shown in FIG. 4, in view of the longitudinal direction of the wavelength conversion member 11, a line N perpendicular to the upper surface of this member is not parallel to but inclined from the optical axis L_{F} of the light condenser 13. Consequently, the distance from the light condenser 13 to the upper surface of the wavelength conversion member 11 is different according to the position in the vertical direction. More specifically, the distance from the light condenser 13 to the upper surface of the wavelength conversion member 11 decreases downward while increasing upward. As described above, what is called the focal plane at the one focal point F₁ of the light condenser 13 and the upper surface of the wavelength conversion member 11 are not parallel to each other. As shown in FIG. 4, the width A₂ of the fluorescent layer 112 of the wavelength conversion member 11 is larger than the width A₁ of a region where the visual field (condensing width) of the light condenser 13 is projected on the surface of the wavelength conversion member, and the region (the region indicated by A₁) where the visual field of the light condenser 13 is projected is disposed in the range of the fluorescent layer 112 of the wavelength conversion member 11. Such a configuration can condense the fluorescent light from the wavelength conversion member 11 having a larger width than the visual field (condensing width) of the light condenser 13 does. Consequently, the light quantity can be increased.

Incidentally, the imaging element (rod lens etc.) provided for the light condenser 13 can transfer (image (focus)) an image from the plane (what is called the focal plane) that is perpendicular to the optical axis L_{F} and contains the one focal point F₁ in view of the longitudinal direction of the light condenser 13 to the plane (what is called the focal plane) that contains the other focal point F₂. Consequently, to improve MTF, it is preferred that in view of the longitudinal directions of the wavelength conversion member 11 and the light condenser 13, the upper surface (light emission surface) of the wavelength conversion member 11 be positioned on the one focal point F₁ of the light condenser 13, and the angle β between the straight line N perpendicular to the upper surface and the optical axis L_{F} of the light condenser 13 be 0° (parallel). On the other hand, to increase the quantity of fluorescent light entering the light condenser 13, it is preferred to increase the area of “a region of the fluorescent layer 112 of the wavelength conversion member 11 that actually emits the fluorescent light (the region where radiation is incident and fluorescent light is emitted)” that resides in the visual field of the light condenser 13. To increase the area, it is preferred that in view of the longitudinal directions of the wavelength conversion member 11 and the light condenser 13, the more closely the angle β between the straight line N perpendicular to the upper surface of the wavelength conversion member 11 and the optical axis L_{F} of the light condenser 13 approaches 90° (right angle), the more preferable it is.

As described above, in view of the longitudinal directions of the wavelength conversion member 11 and the light condenser 13, for the sake of improvement in MTF, the closer to the 0° (parallel) the angle β between the straight line N perpendicular to the upper surface of the wavelength conversion member 11 and the optical axis L_{F} of the light condenser 13 is, the more it is preferable; for the sake of the light quantity (luminance), the closer to the 90° (right angle) this angle is, the more it is preferable. Accordingly, in the embodiment of the present invention, to facilitate achievement of both of improvement in MTF and improvement in light quantity, in view of the longitudinal directions of the wavelength conversion member 11 and the light condenser 13, the angle β between the straight line N perpendicular to the upper surface of the wavelength conversion member 11 and the optical axis L_{F} of the light condenser 13 is configured as 45°. Such a configuration can facilitate achievement of both improvement in MTF (or suppression of reduction) and increase in light quantity (luminance) (or suppression of reduction).

To improve MTF, it is preferred that the other focal point F₂ of the light condenser 13 be disposed at the light receiving part 41 of the photoelectric conversion element 4, and the optical axis L_{F} of the light condenser 13 and the surface of the light receiving part 41 form 90° (right angle) in view of the longitudinal direction of the light condenser 13. Accordingly, in the embodiment of the present invention, the photoelectric conversion element 4 is provided so that the surface of the light receiving part 41 and the optical axis L_{F} of the light condenser 13 can form the right angle in view of the longitudinal direction of the light condenser 13.

### (Supporting Part)

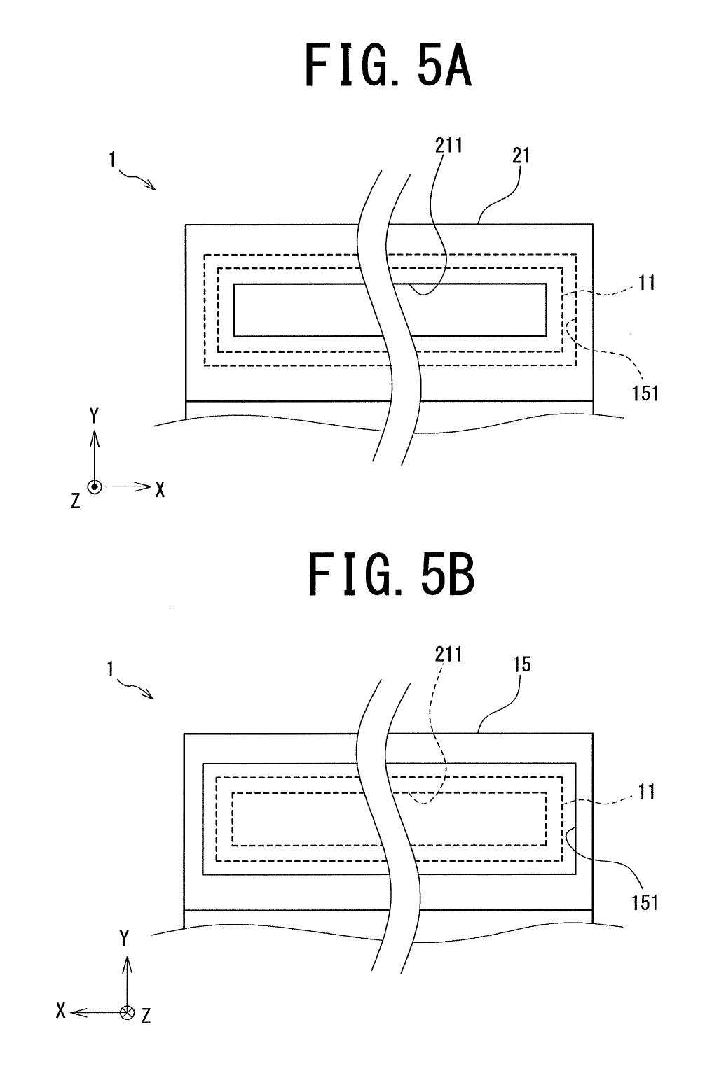

Next, the configuration example of the supporting part 15 is described with reference to FIGS. 5A and 5B. FIGS. 5A and 5B are diagrams schematically showing configuration examples of the second opening 211 provided for the first blocking member 21 and the first opening 151 provided for the supporting part 15. FIG. 5A is a diagram in view from the side (upper side) where radiation is incident. FIG. 5B is a diagram in view from the side opposite to the side (lower side) where radiation is incident. The wavelength conversion member 11 is provided on the upper surface of the supporting part 15, and the first blocking member 21 is provided on the upper side of the supporting part 15 and the wavelength conversion member 11 (see FIG. 3).

The second opening 211 provided for the first blocking member 21 has an elongated shape in the longitudinal direction of the housing 14, for example. A slit-shaped through-hole penetrating in the radiation incident direction is applied thereto. Likewise, the first opening 151 provided for the supporting part 15 has an elongated shape in the longitudinal direction of the housing 14. A slit-shaped through-hole penetrating in the radiation incident direction (vertical direction) is applied thereto. As shown in FIGS. 5A and 5B, in view of the radiation incident direction (in the vertical directional view), the second opening 211 provided for the first blocking member 21 is disposed (housed) in the first opening 151 provided for the supporting part 15 and the outer periphery (outline) of the wavelength conversion member 11. That is, in the vertical directional view, the inner periphery of the first opening 151 provided for the supporting part 15 is disposed at the outermost side. The wavelength conversion member 11 is disposed so as to be housed therein. Furthermore, the second opening 211 provided for the first blocking member 21 is disposed so as to be housed in the outer periphery of the wavelength conversion member 11.

The configuration where the supporting part 15 is provided with the first opening 151 as described above can reduce the area where the incident radiation can be scattered. In particular, in the case where the first opening 151 has a through-hole-shaped configuration penetrating in the vertical direction, radiation incident from the upper side passes through the first opening 151. Consequently, radiation scattering at the supporting part 15 can be suppressed. Accordingly, entrance of the radiation scattered by the supporting part 15 into the sensor substrate 12 can be prevented or suppressed. Consequently, occurrence of noise at the sensor substrate 12 can be prevented or suppressed.

In particular, in the case where the inner periphery of the first opening 151 provided for the supporting part 15 is disposed more outer than the inner periphery of the second opening 211 provided for the first blocking member 21 in the vertical directional view, the radiation having passed through the second opening 211 of the first blocking member 21 passes through the first opening 151 provided for the supporting part 15. Accordingly, as entrance of radiation directly into the upper surface of the supporting part 15 is prevented or suppressed, the advantageous effect of preventing or suppressing radiation scattering can be improved.

That is, according to a configuration where the supporting part 15 is not provided with the first opening 151 or a case where the first opening 151 provided for the supporting part 15 is disposed inside of the second opening 211 provided for the first blocking member 21 in the vertical directional view, the radiation having passed through the second opening 211 provided for the first blocking member 21 and the wavelength conversion member 11 is incident on the upper surface of the supporting part 15. Accordingly, the radiation incident on the upper surface of the supporting part 15 is reflected and scattered, and the scattered radiation sometimes enters the photoelectric conversion element 4 of the sensor substrate 12 or the wiring board 3. As a result, in the photoelectric conversion element 4 and the wiring board 3, noise due to the incident radiation sometimes occurs. On the contrary, the embodiment of the present invention prevents or suppresses entrance of the radiation into the upper surface of the supporting part 15 as described above. Consequently, scattering of the radiation on the upper surface of the supporting part 15 can be prevented or suppressed. Consequently, occurrence of noise due to the scattered radiation can be prevented or suppressed.

The third blocking member 23 is provided on the one side surface (the side surface on which the supporting part 15 is provided) of the housing 14. Such a configuration can further improve the advantageous effect of suppressing noise caused by entrance of radiation in the photoelectric conversion element 4 and the wiring board 3 on the sensor substrate 12. That is, as described above, when the radiation scattered by the surface of the wavelength conversion member 11 enters the photoelectric conversion element 4 and the wiring board 3 on the sensor substrate 12, noise due to entrance of the radiation into the photoelectric conversion element 4 and the wiring board 3 sometimes occurs. Here, the third blocking member 23 is provided so as to cover the one side of the housing 14, thereby suppressing entrance of the radiation scattered at the wavelength conversion member 11 into the photoelectric conversion element 4 and the wiring board 3 on the sensor substrate 12. In other words, the third blocking member 23 is provided between the sensor substrate 12 and the wavelength conversion member 11, thereby suppressing entrance of the radiation reflected and scattered at the wavelength conversion member 11 into the photoelectric conversion element 4 and the wiring board 3 on the sensor substrate 12. Consequently, the advantageous effect of suppressing noise caused by entrance of radiation in the photoelectric conversion element 4 and the wiring board 3 on the sensor substrate 12 can be further improved.

In the embodiment of the present invention, in view of the longitudinal directions of the wavelength conversion member 11 and the light condenser 13, the optical axis L_{X} of the incident radiation and the optical axis L_{F} of the light condenser 13 form the right angle. According to such a configuration, in the vertical directional view, the sensor substrate 12 is not necessarily provided at a position overlapping the second opening 211 of the first blocking member 21. A configuration is then adopted where in the vertical directional view, the sensor substrate 12 (the wiring board 3 and the photoelectric conversion element 4) is provided at a position deviating from the first blocking member 21 and the supporting part 15. In particular, a configuration is adopted where this substrate is provided at a position deviated from (not overlapping) the second opening 211 of the first blocking member 21. Accordingly, the radiation having passed through the first blocking member 21 can be prevented from entering the sensor substrate 12. Consequently, occurrence of noise in the sensor substrate 12 can be prevented or suppressed. Furthermore, in the vertical directional view, the configuration where the sensor substrate 12 is provided at the position deviated from the second opening 211 of the first blocking member 21 is adopted, which can provide the second blocking member 22 on the upper side of the sensor substrate 12. Consequently, as the second blocking member 22 can prevent the radiation from entering the sensor substrate 12, the advantageous effect of preventing or suppressing occurrence of noise in the sensor substrate 12 can be improved.

The fourth blocking member 24 is provided on the other side surface of the housing 14. In the state where the fourth blocking member 24 is provided, a state is achieved where the other side surface of the housing 14 is covered with the fourth blocking member 24. Accordingly, a state is achieved where the sensor substrate 12 housed in the sensor substrate housing part 143 is covered with the fourth blocking member 24, and entrance of radiation from the second surface 32 side of the sensor substrate 12 can be prevented or suppressed. Consequently, occurrence of noise in the sensor substrate 12 can be prevented or suppressed.

### <Radiation Detection Apparatus>

Next, the configuration example of a radiation detection apparatus 5 is described with reference to FIG. 6. FIG. 6 is a sectional view schematically showing a configuration example of the radiation detection apparatus 5. The radiation detection apparatus 5 includes the radiation source 51, and the radiation detector 1 according to the embodiment of the present invention. The radiation source 51 that can emit linear radiation is applied as this radiation source 51. The radiation source 51 may have any configuration only if this source can emit linear radiation, and is not limited to a specific configuration. The radiation source 51 and the radiation detector 1 are disposed to face each other with the conveyance path P for the object Q being interposed therebetween. The radiation emitted from the radiation source 51 transmits through the object Q conveyed on the conveyance path P, and enters the radiation detector 1. The radiation detector 1 performs the operation described above, thereby generating and outputting a two-dimensional radiation image signal (radiation image data) that includes the internal information on the object Q.

The embodiments of the present invention have been described above in detail. The embodiments described above only show specific examples for implementing the present invention. The technical scope of the present invention is not limited to the embodiments described above. Various alterations can be made without departing from the spirit of the present invention.

For example, although the embodiments described above show the configurations where the photodiode array is applied as the photoelectric conversion element, the photoelectric conversion element is not limited to the photodiode array. The photoelectric conversion element may be any element that can perform photoelectric conversion of fluorescent light (visible light) emitted from the fluorescent layer.

The present invention can be effectively used for a radiation detector that includes a fluorescent layer and a photoelectric conversion element that photoelectrically converts fluorescent light emitted from the fluorescent layer, and for a radiation detection apparatus that includes the radiation detector. The present invention can suppress noise caused by entrance of radiation.

The present invention can suppress entrance of the radiation scattered by the fluorescent body into the photoelectric conversion part while preventing or suppressing reduction in resolution.

It should be noted that the above embodiments merely illustrate concrete examples of implementing the present invention, and the technical scope of the present invention is not to be construed in a restrictive manner by these embodiments. That is, the present invention may be implemented in various forms without departing from the technical spirit or main features thereof.

What is claimed is:

1. A radiation detector, comprising:
an elongated wavelength conversion part that emits fluorescent light according to incident radiation;
a photoelectric conversion part that receives the fluorescent light emitted from the wavelength conversion part, and generates an electrical signal; and
a light condensing part that is disposed between the wavelength conversion part and the photoelectric conversion part, and focuses the fluorescent light emitted from the wavelength conversion part on the photoelectric conversion part,
wherein in view of a longitudinal direction of the wavelength conversion part, an optical axis of radiation incident on the wavelength conversion part, and an optical axis of the light condensing part are in directions different from each other, and
one focal point of the light condensing part is disposed on the wavelength conversion part, and another focal point of the light condensing part is disposed on the photoelectric conversion part.

2. The radiation detector according to claim 1, wherein in view of a longitudinal direction of the wavelength conversion part, an angle between an optical axis of radiation incident on the wavelength conversion part and an optical axis of the light condensing part ranges from 45° to 135°.

3. The radiation detector according to claim 1, wherein in view of a longitudinal direction of the wavelength conversion part, an angle between an optical axis of radiation incident on the wavelength conversion part and an optical axis of the light condensing part is 90°.

4. The radiation detector according to claim 1, wherein in view of a longitudinal direction of the wavelength conversion part, an angle between a line perpendicular to a plane of the wavelength conversion part oriented toward the photoelectric conversion part and an optical axis of the light condensing part is 45°.

5. The radiation detector according to claim 1, wherein a blocking part that blocks the radiation is provided between the wavelength conversion part and the photoelectric conversion part.

6. The radiation detector according to claim 5, wherein the blocking part that blocks the radiation is provided between the wavelength conversion part and the light condensing part.

7. The radiation detector according to claim 5, wherein the blocking part that blocks the radiation is provided between the light condensing part and the photoelectric conversion part.

8. The radiation detector according to claim 6, wherein the blocking part allows visible light to transmit through this blocking part.

9. The radiation detector according to claim 7, wherein the blocking part allows visible light to transmit through this blocking part.

10. The radiation detector according to claim 8, wherein the blocking part is provided on an optical path of the light condensing part.

11. The radiation detector according to claim 9, wherein the blocking part is provided on an optical path of the light condensing part.

12. The radiation detector according to claim 5, wherein the blocking part is provided with an opening that allows fluorescent light emitted from the wavelength conversion part to pass through this opening.

13. The radiation detector according to claim 1, wherein the photoelectric conversion part is provided so as to face a plane on which radiation of the wavelength conversion part is incident.

14. A radiation detection apparatus, comprising:
a radiation source; and
a radiation detector that detects radiation emitted by the radiation source,
wherein the radiation detection apparatus generates a radiation image of an object between the radiation source and the radiation detector, and
the radiation detector is the radiation detector according to claim 1.
